(19) United States
(12) Patent Application Publication
(10) Pub. No.: US 2023/0099923 A1
(43) Pub. Date: Mar. 30, 2023

(54) SOLAR CELL WITH A TRANSPARENT CONDUCTOR COMPRISING AN EMBEDDED METAL GRID

(71) Applicant: 3M INNOVATIVE PROPERTIES COMPANY, St. Paul, MN (US)

(72) Inventors: Daniel M. Pierpont, North St. Paul, MN (US); John J. Sullivan, Hudson, WI (US); Robert L. Brott, Woodbury, MN (US); Mark B. O'Neill, Stillwater, MN (US); Mark D. Weigel, Hugo, MN (US); Raymond P. Johnston, Lake Elmo, MN (US)

(21) Appl. No.: 17/936,597

(22) Filed: Sep. 29, 2022

Related U.S. Application Data
(60) Provisional application No. 63/261,867, filed on Sep. 30, 2021.

(51) Int. Cl. H01L 33/42; H01L 33/62

(52) U.S. Cl. CPC H01L 33/42; H01L 33/62

(57) ABSTRACT

A solar cell is described that comprises a transparent conductor sheet having a polymeric substrate with an embedded metal grid, disposed within microchannels extending partially through a thickness of polymeric substrate from a first surface of the polymeric substrate; and a photoactive layer disposed adjacent to the first surface of the polymeric substrate. The transparent conductor sheet has a sheet resistance less than 1 Ω/□ and an average solar direct transmittance over the visible and infrared portion of the spectrum of at least about 80%.

### CROSS REFERENCE TO RELATED APPLICATION

This application claims priority from U.S. Provisional Application Ser. No. 63/261,867, filed Sep. 30, 2021, the disclosure of which is incorporated by reference in its/their entirety herein.

### BACKGROUND OF THE INVENTION

### Field of the Invention

The present invention is directed to a transparent conductor sheet for use in a solar cell, in particular, the transparent conductor sheet comprises a conductive metal grid.

### Background

Conventional photovoltaic (PV) modules comprise a plurality of silicon solar cells, such as solar cell 20 shown in FIG. 1, which absorb light and generate electrical current. Solar cell 20 includes busbars 25 on the front major surface 21 of the semiconductor material forming the solar cell that interconnect and collect electrical charge from the conductive fingers 23 which are made of a conductive metal such as copper, silver or aluminum. Busbars 25 are thin strips of a highly conductive metal (typically silver coated copper) that are connected to conductive fingers 23. The electrical current is collected by the conductive fingers. Typically, tin-lead coated copper ribbons are soldered onto the busbars to transfer electrical current out of the solar cells.

Transparent conducting oxides, such as indium tin oxide (ITO), silver nanowires, carbon nanotubes and graphene layers have been looked at as a means of collecting the electrical current generated by solar cells. The charge collection layer in a solar cell should have a low sheet resistance and high optical transparency. In addition, good flexibility is needed for new flexible solar technologies (i.e., perovskite solar cells, dye-sensitized solar cells, organic photovoltaic solar cells, copper indium gallium selenide, etc.).

Transparent conductive oxides are commonly used in the solar industry for this purpose. The use of transparent conductive oxide layers in solar cells may have a negative impact on the efficiency of the solar cell. For example, it is known that indium tin oxide (ITO) has limitations in its current carrying capacity. Solar cell developers would like to have ITO layers that have a sheet resistance 10 range. The resistance of ITO layers can be reduced by increasing the thickness of the ITO layer. However, this can lower the transmission of visible light through the ITO layer which can negatively affect solar cell efficiency, make the layer less flexible and result in increased expense due to the use of more expensive/rare indium.

Thus, there is a need for innovative new current capture materials that are flexible, have low sheet resistance and are transmissive to visible light.

### SUMMARY

In a first embodiment, a solar cell is described. The solar cell comprises a transparent conductor sheet comprising a polymeric substrate with an embedded metal grid, disposed within microchannels extending partially through a thickness of polymeric substrate from a first surface of the polymeric substrate; and a photoactive layer disposed adjacent to the first surface of the polymeric substrate. The transparent conductor sheet has a sheet resistance less than 1Ω/□ and an average solar direct transmittance over the visible and infrared portion of the spectrum of at least about 80%.

In a second embodiment, a transparent conductor sheet is described. The transparent conductor sheet comprises a polymeric substrate with an embedded metal grid, disposed within grooves formed in a first surface of the polymeric substrate, and a barrier assembly disposed on a second surface of the polymeric substrate, wherein the barrier film consists of an inorganic oxide layer disposed between first and second polymer layers, wherein the first and second polymer layers each comprise a polymeric reaction product of at least one of acrylic or methacrylic monomers.

In a third embodiment, a method of making a flexible solar cell is described. The method comprises providing a transparent conductor sheet, wherein the transparent conductor sheet comprises a polymeric substrate with an embedded metal grid, disposed within grooves extending partially through a thickness of polymeric substrate from a first surface of the polymeric substrate, optionally, applying an electron/hole transport layer on the first surface of the transparent conductor sheet; and applying a photoactive layer on one of the first surface of the transparent conductor sheet or the electron/hole transport layer.

The above summary of the present invention is not intended to describe each illustrated embodiment or every implementation of the present invention. The figures and the detailed description that follows more particularly exemplify these embodiments.

### BRIEF DESCRIPTION OF THE DRAWINGS

The present invention will be further described with reference to the accompanying drawings, wherein:

FIG. 1 is a schematic top view of a conventional silicon solar cell.

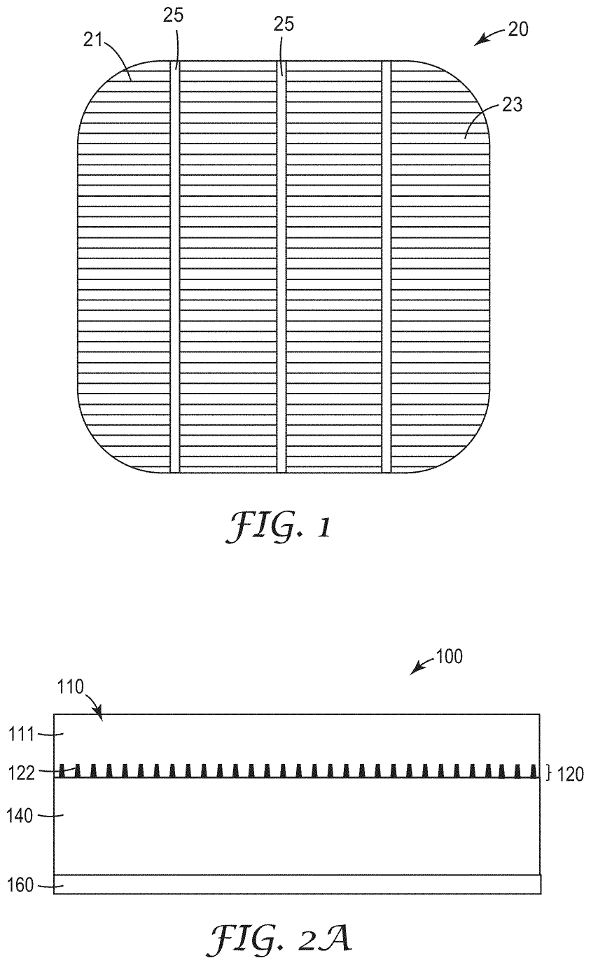

FIG. 2A-2C are three schematic cross-sectional views of a solar cell according to the present invention.

FIGS. 3A-3C are three views of an exemplary conductive sheet according to the present invention.

FIG. 4 is a diagram of an alternative exemplary conductive sheet according to the present invention.

FIGS. 5A-5B are two views of another alternative exemplary conductive sheet according to the present invention.

FIG. 6 is a diagram of another alternative exemplary conductive sheet according to the present invention.

FIG. 7 is a schematic cross-sectional view of an alternative solar cell according to the present invention.

FIGS. 8A and 8B are graphs showing the probability of the embedded grid in the exemplary conductive sheet of the present invention becoming completely disconnected as a function of the fraction of broken connections in the grid.

FIG. 9 is a graph that illustrates the change in sheet resistance of an embedded grid in the exemplary conductive sheet of the present invention as a function of the fraction of broken connections in the grid.

FIG. 10 is a graph showing transparent conductor figure-of-merit for different transparent conductor materials.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the invention as defined by the appended claims.

### DETAILED DESCRIPTION OF THE EMBODIMENTS

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “forward,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

A solar cell is described herein that comprises a transparent conductor sheet having an exposed metal grid that is in contact a photo active layer(s) of the cell. The metal grid of the transparent conductor sheet is disposed within microchannels formed in a surface of and partially extending through a polymeric substrate, such that metal grid is exposed at a first surface of the polymeric substrate. The exemplary transparent conductor sheets are flexible. The term “flexible” as used herein refers to being capable of being formed into a roll.

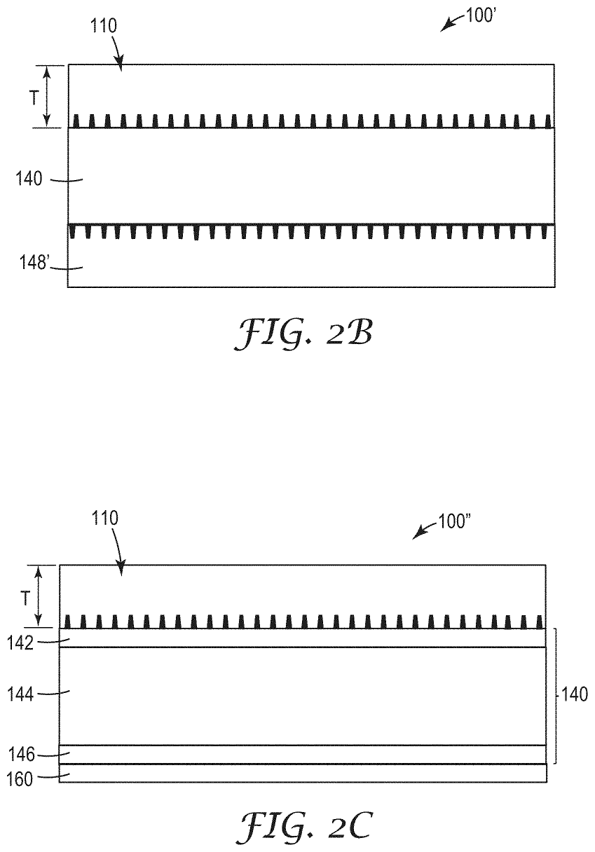

FIG. 2A is schematic cross section of a portion of a first exemplary solar cell assembly 100. In this embodiment, a transparent conductor sheet 110 is disposed on an active portion 140 of a photovoltaic cell and a bottom electrode 160, wherein the transparent conductor sheet can serve as a top electrode for the photovoltaic cell, wherein the transparent conductor sheet 110 comprises a polymeric substrate 111 with an embedded metal grid 120. The embedded metal grid comprises a plurality of intersecting solid metal conductive elements 122.

Active potion comprises a semiconductor element with a junction of the type (n+n(or p)p+) on the basis of mono- or multi-crystalline silicon, amorphous silicon, heterojunction with intrinsic thin layer (HIT), and other thin-film semiconductors. Electrodes 110, 160 are disposed on each surface of the active portion, which collect and carry off the generated electrical energy. The active portion of the photovoltaic cell further comprises a single layer or a plurality of solar cell layers, such as solar cell layers 142, 144, 146 shown in FIG. 2C.

In an exemplary aspect, other thin-film semiconductors include the active layers used in organic photovoltaic cells, copper indium gallium selenide cells, dye sensitized cells, cadmium telluride, gallium arsenide, and amorphous silicon, and perovskite solar cells.

In another alternative embodiment, the bottom electrode 148′ can be a second transparent conductor sheet 110′ as shown in FIG. 2B. Thus, the exemplary transparent conductor sheets, described herein, can serve as the top and/or bottom electrode replacing conventional electrode materials and structures such as screen printed silver conductive elements (e.g., fingers and busbars), metal electrodes, or vapor coated metals or metal oxides.

As shown in FIG. 2C, solar cell assembly 100″ can be a Perovskite cell, wherein the active portion 140, comprise a perovskite layer 144, a hole transport layer 142 and an electron transport layer 146. In some embodiments, perovskite layer 144 can include a scaffold (not shown) that is coated with the perovskite-structured compound, such as a hybrid organic-inorganic lead or tin halide-based material.

The electron transport layer can comprise a titanium oxide (TiO₂) layer, a tin oxide (SnO₂) layer or a zinc oxide (ZnO) layer and the hole transport layer 142 can comprise a poly(3,4-ethylenedioxythiophene) polystyrene sulfonate (PEDOT:PSS) layer, nickel oxide (NiOₓ) layer, or NiOₓ/cuprous thiocyanate (CuSCN) layer. In an exemplary embodiment, the electron transport layer has a thickness that is less than 40 nm, preferably less than 20 nm, more preferably less than 10 nm. In another exemplary embodiment, the hole transport layer has a thickness between about 50 nm and about 200 nm.

In some embodiments, the location of the hole transport layer 142 and the electron transport layer can be reversed such that the hole transport layer is disposed between the perovskite layer and the bottom electrode and the electron transport layer is disposed between the top electrode and the perovskite layer(s). Transparent conductor sheet 110 described herein can be utilized as the top and/or bottom electrode in a perovskite cell.

In another example, solar cell assembly 100 can be a heterojunction with intrinsic thin layer (HIT) solar cell, wherein the active portion 140 comprise a crystalline silicon wafer having an n-type amorphous silicon layer disposed on one surface of the crystalline silicon and a p-type amorphous silicon layer disposed on the other surface of the crystalline silicon. The HIT cell can further include indium tin oxide (ITO) layers (not shown) between the electrodes 110, 160 and active portion 140. The transparent conductor sheet 110 described herein can be utilized as the top and/or bottom electrode in the HIT cell.

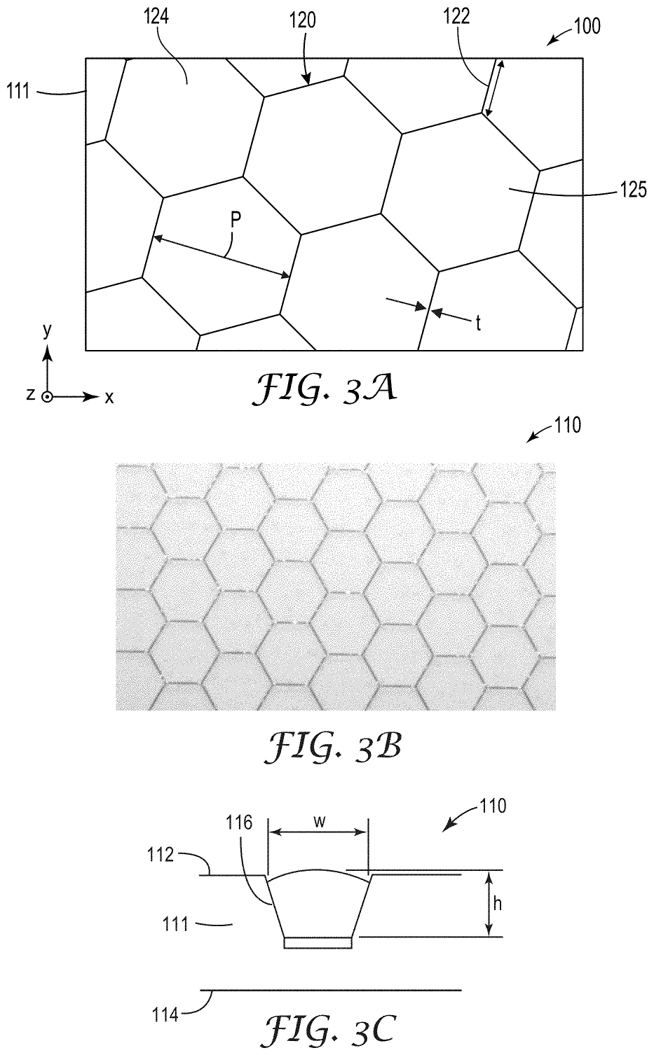

FIGS. 3A-3B, 4, 5A-5B and 6 show exemplary examples of transparent conductor sheets 110, 210, 310, 410 that can be used in a solar cell assemblies as described above.

Referring to FIGS. 3A-3C, transparent conductor sheet 110 comprises a polymeric substrate 111 extending along orthogonal first and second directions (i.e., in the x-y plane), and a plurality of intersecting electrically conductive elements 122 forming a conductive grid 120 embedded at least partially in a first surface 112 (FIG. 3C) of the polymer substrate, wherein the conductive elements are formed of solid metal. Specifically, FIGS. 3A-3B show a transparent conductor sheet 110 having a hexagonal embedded grid 120.

In some embodiments, the embedded grid 120 is a unitary metallic body. The conductive elements 122 comprise a solid metal that can be selected from gold, silver, palladium, platinum, aluminum, copper, nickel, tin, and alloys thereof. In some embodiments, conductive elements 122 consist essentially of copper, nickel, or silver. The conductive elements of the embedded grid form an open mesh having a repeating cell 124 geometry disposed at least substantially in the polymeric substrate. In this instance the phrase “substantially in” means that at least 90%, preferably 95% of the height of each conductive element of the embedded grid resides within groove 116 formed in a first surface 112 of the polymeric substrate 110 as shown in FIG. 3C.

The embedded grid is an open mesh that can include various arrangements of polygonal cell geometries with the conductive elements forming straight line borders. As used herein, the geometry of a cell refers to its shape, and is distinguished from its dimension(s). Cell geometries include squares, non-square rectangles, hexagons, octagons, other polygons, or other free-form shapes. When the embedded grid is formed by a repeating pattern of cells, the cell pitch, p, of the embedded grid is defined as the distance between the center line of conductive elements on opposite sides of the repeating pattern. In an exemplary aspect, the cell pitch of the embedded grid is between 100 microns and 5000 microns.

In one exemplary embodiment, the conductive elements can be disposed at a 1 mm pitch and have a width of 25 microns and a height of 25 microns.

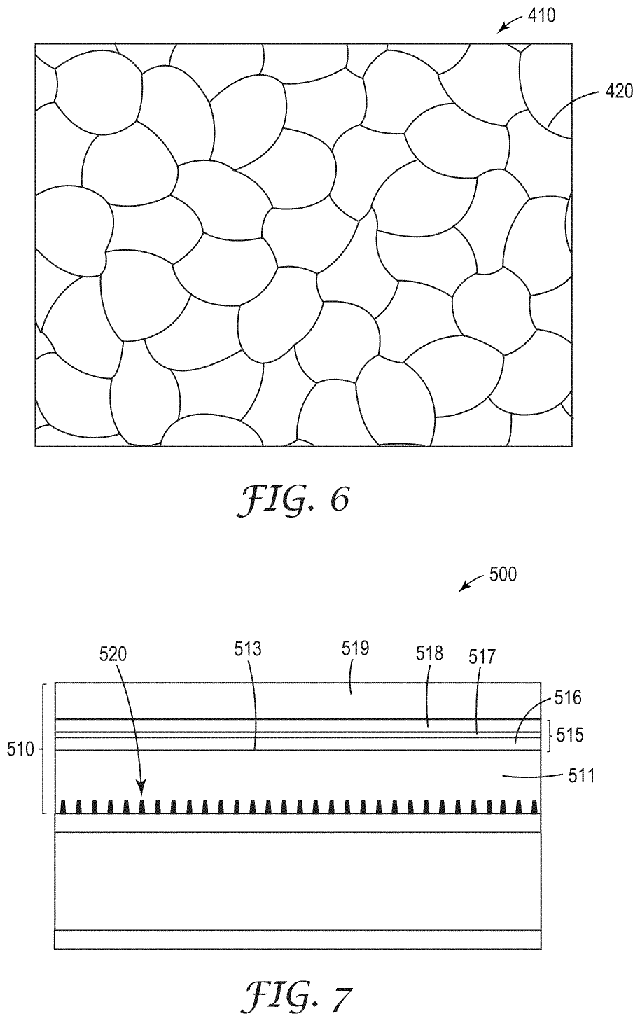

Alternatively, the cells may also be defined by wavy or irregular linear conductive elements, provided that the cells form a micropattern having a generally repeating pattern. The repeating pattern can be on the single cell level or can comprise a plurality of cells. In some embodiments, the embedded grid may have a random pattern of cells in the form of a bubble mesh such as the embedded grid 420 shown in FIG. 6. The cell pitch of the cells in this embodiment is measure of the average diameter of the cells. Hence, it is within the scope of this disclosure for a cell geometry to include multiple cells having different geometries and/or different sizes, provided that the grid comprises a mesh of intersecting conductive elements.

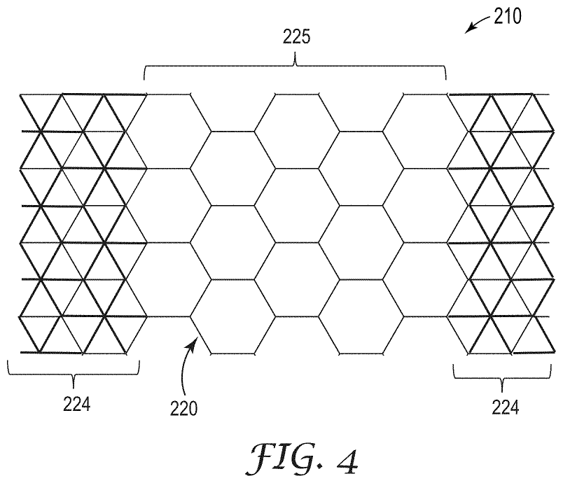

FIG. 4 shows a schematic diagram of transparent conductor sheet 210 having an embedded grid 220 comprising a mixture of hexagonal and triangular cells creating areas of a low-density embedded grid 225 and a high-density embedded grid 224. The low-density embedded grid 215 can collect charges from across the surface of the active portion of the solar cell while the high-density embedded grid 214 can be capable of carrying higher electrical currents than the low-density portions and can serve as busbars to take the collected electrical charge from the low-density embedded grid and transfer electrical current out of the solar cell. Using the high-density portion as busbars eliminates the need for separate busbar structures and may improve efficiency of the solar cell due to the fact that the high-density portions are not solid structures which prevent light from reaching the active area layers of the solar cell. The cell pattern in the low- and high-density portions can have the same or different geometries.

Referring back to FIGS. 3A and 3B, conductive element 122 extends partially through the thickness, t, of the polymer substrate 111. In an alternative embodiment, the conductive grid is disposed in the polymer substrate such that the top surface of the embedded grid 120 is proximate to the first surface 112 of the polymer substrate 111. Each cell in the embedded grid has a central open or plateau portion 125 of exposed polymeric substrate surrounded by electrically conductive elements 122.

In some embodiments, exemplary polymer substrate 111 can be a visible light transparent film comprising a thermoplastic resin (e.g., cyclic olefin polymer, polyethylene terephthalate (PET), polymethyl methacrylate (PMMA), polycarbonate (PC), polycarbonate co-polymers, and polyethylene naphthalate (PEN), polypropylene, ethylene and acrylic acid (EAA) copolymers, ethylene methyl acrylate (EMA) copolymer, an ethylene vinyl acetate (EVA) polymer or other optically transparent thermoplastic resins known in the art). The polymeric substrate is sufficiently flexible and strong to be processed in a roll-to-roll fashion. By roll-to-roll, what is meant is a process where material is wound onto or unwound from a support, as well as further processed in some way. Examples of further processes include coating, slitting, blanking, and exposing to radiation, or the like. Polymeric films can be manufactured in a variety of thicknesses, ranging in general from about 10-200 microns. In many embodiments, polymeric film thicknesses range from about 20 μm to about 150 μm, or from about 50 μm to about 125 μm.

Grooves 116 containing the embedded grid can be formed by embossing or molding the polymer substrate at an elevated temperature. The depth of the grooves can be between 1 micron and 100 microns, preferably between 5 microns and 20 microns.

In other embodiments, the exemplary polymer substrate can be a cured resin that was cured against a tool to form the grooves in which the embedded grid resides. The cured resin may be an acrylate resin, an epoxy resin, or other curable resin chemistry.

Conductive elements 122 may be formed in grooves disposed in the first surface of the polymeric substrate. The grooves may be formed in the polymeric substrate using photolithography processes, embossing or microreplication. In some embodiments, conductive elements can have a large aspect ratio (element height/element width). Having conductive elements with a large aspect ratio may be desired for applications where a high transparency and a high electrical conductance is desired. For example, increasing the open area fraction (the amount of exposed plateau portions) can increase the transparency but would lower the electrical conductance for conductive elements having a fixed cross section. Increasing the element height, h, of the conductive elements while maintaining the element's width, w, leads to a higher aspect ratio which can result in a decrease of the sheet resistance of the transparent conductor sheet, thus, increasing the electrical conductance of the transparent conductor sheet.

The crown of the conductive element can be at or slightly above or below the plane of the first surface of the transparent conductor sheet such that the height of the conductive element is between 70% and 130% of the groove depth, preferably between 90% and 110%, more preferably between 95% and 105%. In some embodiments, the conductive elements can have a width of between about 2 microns and 100 microns and a height of between about 3 microns and 100 microns. In other embodiments, the conductive elements can be characterized by having an aspect ratio (element height/element width) that is greater than 0.5, or greater than 1 or greater than 2.

The sides of the conductive elements may be inclined with respect to the first surface of the transparent conductor.

In some embodiments, the conductive elements of the embedded grid can be shaped to redirect reflected light that would otherwise exit the solar cell back onto a surface of the photoactive layer. Redirecting the non-absorbed light onto the photoactive layers can increase the power output of the solar cell. For example, with the conductive element oriented with the narrow portion toward the light source, a base angle of the conductive element larger than 45 deg plus one half the critical angle of the medium surrounding the element will direct the light toward the photoactive layer wherein the critical angle is defined by Snell's law as the inverse sin of the reciprocal of the refractive index of the surrounding medium.

In an exemplary aspect, the transparent conductor sheet 110 is transmissive to visible and infrared light. The term “transmissive to visible and infrared light” as used herein can mean having an average solar direct transmittance of at least about 75% (in some embodiments at least about 80, 85, 90, 92, or 95%) measured along the normal axis of the conductor sheet in the wavelength range of 300-2500 nm. Calculation of the solar direct transmittance is described in ISO9050. In some embodiments, the visible and infrared light-transmissive assembly has an average solar direct transmittance over a range of 350 nm to 1500 nm of at least about 75% (in some embodiments at least about 80, 85, 90, 92, or 95%). Visible and infrared light-transmissive assemblies are those that do not substantially interfere with absorption of visible and infrared light, for example, by photovoltaic cells.

As mentioned previously, the transmissivity of the conductor sheet depends on the open area fraction of the conductor sheet. The term “open area fraction” as used herein can mean the area of exposed plateau portions divided by the total area of the conductor sheet. In an exemplary embodiment, the open area fraction of the conductor sheet at least about 80% (in some embodiments at least about 90, 92, 95, 97, or 98%).

In some embodiments, the conductive elements of the embedded grid can be generated by any appropriate patterning method, e.g., methods that include photolithography with etching or photolithography with plating (see, e.g., U.S. Pat. Nos. 5,126,007; 5,492,611; 6,775,907). In some embodiments, the conductive elements are formed by an electroplating process on a conductive seed layer disposed in the bottoms of the grooves, such as is described in PCT Publication No. WO2020/227280, herein incorporated by reference. Forming the conductive elements by a plating process creates solid metal conductive elements resulting in a transparent conductive sheet having a lower sheet resistance than if the conductive elements were formed from a conductive ink or paint that comprises conductive particles. The sheet resistance of the exemplary conductor sheets is less than 1Ω/□, preferably less than 0.5 Ω/□.

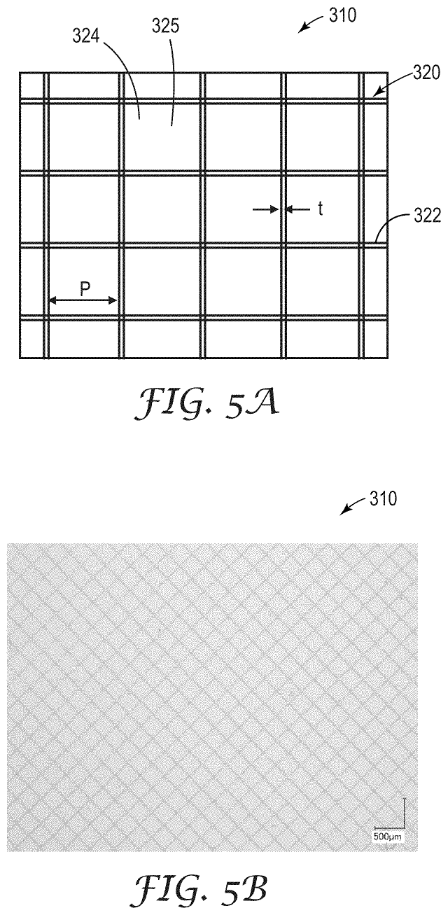

In another embodiment shown in FIGS. 5A-5B, a transparent conductor sheet 310 has a rectangular embedded grid 320. Each cell 324 or rectangle in the grid comprises a central plateau area and conductive elements 322 disposed around the central plateau area 325 wherein the cell pitch, P, is the distance between the centerline of opposing conductive elements 322. The embedded grid and polymeric substrate are substantially similar to those previously described.

As mentioned previously, the transparent conductor sheets described herein are used as one of the top or bottom electrode in a solar cell wherein the conductive grid contacts the active portion of the solar cell. In some embodiments, the transparent conductor sheet(s) can be in direct contact with the active portion of the cell, while in another aspect the transparent conductor sheet(s) can be bonded to the active portion of the solar cell by an adhesive for example a conductive adhesive.

In an exemplary embodiment, a method of forming a solar cell is described. The method comprises forming the active portion of the solar cell directly on the first surface of the transparent conductor sheet by applying one or more photoactive materials such as a perovskite structured material, a photoactive dye layer and an electrolyte layer or an organic photovoltaic assembly comprising a buffer layer, an acceptor layer and a donor layer, on the first surface of the transparent conductor sheet. An electron transport or hole transport layer can be disposed on the active portion. An electrode can then be applied to the exposed surface of the electron transport or hole transport layer.

Optionally, applying an electron transport or hole transport layer can be formed on the first surface of the transparent conductor sheet prior to application of the active portion.

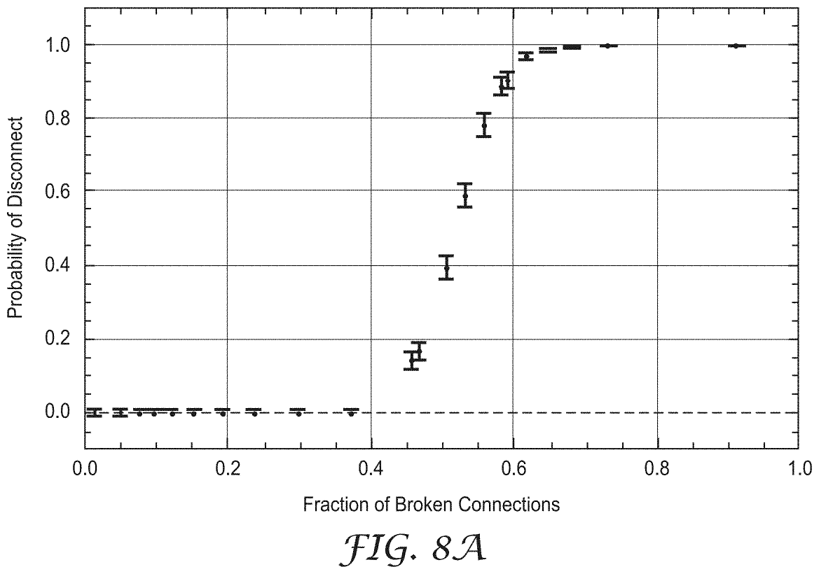

In another exemplary embodiment, the transparent conductor sheet 510 can further comprise a barrier film 515 disposed on a second surface 513 of the polymeric substrate as shown in FIG. 7 in solar cell 500. Barrier film 515 can provide additional UV and mechanical protection of the transparent conductor and the solar cell beneath the barrier film. In particular, the barrier film is disposed between the polymer substrate 111 of the conductor sheet that is exposed to incoming light and the external environment (e.g., weather, moisture, air, dust, etc.). In some embodiments the barrier film can be formed directly on the second surface of the polymeric substrate, while in other embodiments the barrier film can be adhered to the second surface by an adhesive.

Barrier film 515 consists of a visible light-transmissive inorganic oxide layer 517 disposed between first and second polymer layers 516, 518, wherein the first and second polymer layers each comprise a polymeric reaction product of at least one of acrylic or methacrylic monomer. Barrier films are typically selected such that they have oxygen and water transmission rates at a specified level as required by the application. In some embodiments, the barrier film has a water vapor transmission rate (WVTR), less than about 0.01 g/m²/day at 38° C., less than about 0.005 g/m²/day at 38° C. and 100% relative humidity; less than about 0.0005 g/m²/day at 38° C. and 100% relative humidity; or less than about 0.00005 g/m²/day at 38° C. and 100% relative humidity. In some embodiments, the barrier film has an oxygen transmission rate of less than about 0.005 g/m²/day at 23° C. and 90% relative humidity; less than about 0.0005 g/m²/day at 23° C. and 90% relative humidity; or less than about 0.00005 g/m²/day at 23° C. and 90% relative humidity.

The inorganic oxide layer 517 can be prepared by atomic layer deposition, thermal evaporation, sputtering, and chemical vapor deposition, while the first and second polymer layers 516, 518 can independently be formed by applying a layer of a volatilizable monomer or oligomer and crosslinking the layer to form the polymer in situ, for example, by flash evaporation and vapor deposition of a radiation crosslinkable monomer followed by crosslinking, for example, using an electron beam apparatus, UV light source, electrical discharge apparatus or other suitable device. The first polymer layer 516 is applied, for example, to the second surface 513 of polymeric substrate 511, and the second polymer layer 518 is typically applied to the inorganic barrier layer 517. The materials and methods useful for forming the first and second polymer layers may be independently selected to be the same or different. The barrier film may be applied as provided in United States Patent Publ. No. 2018-0236756, herein incorporated by reference.

In some embodiments, the first and second polymer layers 516, 518 and inorganic barrier layer 517 are sequentially deposited in a single pass vacuum coating operation with no interruption to the coating process.

Volatilizable acrylate and methacrylate monomers are useful for forming the first and second polymer layers. Volatilizable acrylate and methacrylate monomers may have a molecular weight in the range from about 150 to about 600 grams per mole, or, in some embodiments, from about 200 to about 400 grams per mole. In some embodiments, volatilizable acrylate and methacrylate monomers have a value of the ratio of the molecular weight to the number of (meth)acrylate functional groups per molecule in the range from about 150 to about 600 g/mole/(meth)acrylate group, in some embodiments, from about 200 to about 400 g/mole/(meth)acrylate group. Fluorinated acrylates and methacrylates can be used at higher molecular weight ranges or ratios, for example, about 400 to about 3000 molecular weight or about 400 to about 3000 g/mole/(meth)acrylate group.

Exemplary useful volatilizable acrylates and methacrylates include hexanediol diacrylate, ethoxyethyl acrylate, phenoxyethyl acrylate, cyanoethyl (mono)acrylate, isobornyl acrylate, isobornyl methacrylate, octadecyl acrylate, isodecyl acrylate, lauryl acrylate, beta-carboxyethyl acrylate, tetrahydrofurfuryl acrylate, dinitrile acrylate, pentafluorophenyl acrylate, nitrophenyl acrylate, 2-phenoxyethyl acrylate, 2-phenoxyethyl methacrylate, 2,2,2-trifluoromethyl (meth)acrylate, diethylene glycol diacrylate, triethylene glycol diacrylate, triethylene glycol dimethacrylate, tripropylene glycol diacrylate, tetraethylene glycol diacrylate, neopentyl glycol diacrylate, propoxylated neopentyl glycol diacrylate, polyethylene glycol diacrylate, tetraethylene glycol diacrylate, bisphenol A epoxy diacrylate, 1,6-hexanediol dimethacrylate, trimethylol propane triacrylate, ethoxylated trimethylol propane triacrylate, propylated trimethylol propane triacrylate, tris(2-hydroxyethyl)isocyanurate triacrylate, pentaerythritol triacrylate, phenylthioethyl acrylate, naphthyloxyethyl acrylate, cyclic diacrylates (for example, EB-130 from Cytec Industries Inc. and tricyclodecane dimethanol diacrylate, available as SR833S from Sartomer Co.), epoxy acrylate such as RDX80095 from Cytec Industries Inc., and mixtures thereof. Other useful monomers may include di(meth)acrylate monomers described in U.S. Patent Publication Nos. 2018/0236756, 2018/0136755 and 2018/0244881, herein incorporated by reference in their entirety. Still other monomers that are useful for forming the first and/or second polymer layers include vinyl ethers, acrylonitrile, and mixtures thereof.

The desired chemical composition and thickness of the first polymer layer 516 will depend in part on the nature and surface topography of the polymeric substrate 511. The thickness of the first polymer layer will typically be sufficient to provide a smooth, defect-free surface to which inorganic barrier layer 517 is subsequently applied. For example, the first polymer layer may have a thickness of a few nm (for example, 2 or 3 nm) to about 5 micrometers or more. The thickness of the second polymer layer 518 may also be in this range and may, in some embodiments, be thinner than the first polymer layer.

In some embodiments, one of the polymer layers (e.g., the second polymer layer 518) in the barrier film can be formed from co-depositing coupling agent such as a silane (e.g., an amino silane, cyclic azasiline or a urethane (multi)-(meth)acrylate (multi)-silane) and a radiation-curable monomer (e.g., any of the acrylates listed above). The presence of silanes with reactive groups can form chemical linkages to an optional outer protective layer. Exemplary barrier films may comprise up to 20 wt. %, preferably up to 15 wt. %, of a coupling agent in the second polymer layer to enhance the adhesion of the outer protective layer, such as a polyurethane outer protective layer, to the surface of the second polymer layer.

Useful materials for forming inorganic barrier layer 517 can include metals, metal oxides, metal nitrides, metal carbides, metal oxynitrides, metal oxyborides, and combinations thereof. Exemplary metal oxides include silicon oxides such as silica, aluminum oxides such as alumina, titanium oxides such as titania, indium oxides, tin oxides, indium tin oxide (ITO), tantalum oxide, zirconium oxide, niobium oxide, and combinations thereof. Other exemplary materials include boron carbide, tungsten carbide, silicon carbide, aluminum nitride, silicon nitride, boron nitride, aluminum oxynitride, silicon oxynitride, boron oxynitride, zirconium oxyboride, titanium oxyboride, and combinations thereof. In some embodiments, the inorganic barrier layer comprises at least one of ITO, silicon oxide, or aluminum oxide. In some embodiments, with the proper selection of the relative proportions of each elemental constituent, ITO can be electrically conductive. Enhanced barrier properties may be observed when the inorganic layer is formed by a high energy deposition technique such as sputtering compared to lower energy techniques such as conventional vapor deposition processes. Without being bound by theory, it is believed that the enhanced properties are due to the condensing species arriving at the substrate with greater kinetic energy, leading to a lower void fraction as a result of compaction.

The desired chemical composition and thickness of inorganic barrier layer 517 will depend in part on the nature and surface topography of the underlying layer and on the desired optical properties for the barrier film. The inorganic barrier layers typically are sufficiently thick so as to be continuous, and sufficiently thin so as to ensure that the barrier films will have the desired degree of visible light transmission and flexibility. The physical thickness (as opposed to the optical thickness) of each inorganic barrier layer may be, for example, about 3 nm to about 150 nm (in some embodiments, about 4 nm to about 75 nm). The inorganic barrier layer typically has an average solar direct transmittance of at least about 75% (in some embodiments at least about 80, 85, 90, 92, or 95%) measured along the normal axis to the conductive sheet. In some embodiments, the inorganic barrier layer has an average solar direct transmittance of at least about 75% (in some embodiments at least about 80, 85, 90, 92, or 95%) measured along the normal axis to the conductive sheet. Useful inorganic barrier layers typically are those that do not interfere with absorption of visible or infrared light, for example, by photovoltaic cells.

The transparent conductor sheet 510 may further include a protective layer 519 bonded directly to exposed major surface of the barrier film 515. In an exemplary aspect, the protective film can be a fluoropolymer film, such as ethylene-tetrafluoroethylene (ETFE) film or a polyurethane film, that is adhesively bonded to the upper major surface of the barrier film. In some embodiments the polyurethane film is an ether-based polyurethane. UV stabilizers, such as ultraviolet absorbers (UVAs), Hindered Amine Light Stabilizers (HAT S), and antioxidants may be included in the adhesive used to bond the protective film to the barrier film as a means of protecting the layers beneath the outer protective layer.

The embedded grid 520 of transparent conductor sheet 510 is substantially the same as the embedded grids described previously in that the embedded grid 120 comprises a plurality of intersecting conducting elements arranged in a unitary mesh. The conductive elements 122 comprise a solid metal can be selected from gold, silver, palladium, platinum, aluminum, copper, nickel, tin, and alloys thereof. In some embodiments, conductive elements 122 consist essentially of copper, nickel, or silver. Similarly, the electrical properties and optical properties of transparent conductor sheet 510 are similar those described previously. For example, the sheet resistance of the exemplary conductor sheets is less than 1Ω/□, preferably less than 0.5Ω/□, and the transparent conductor sheet has an average solar direct transmittance over a range of 350 nm to 1500 nm of at least about 75%.

As mentioned preciously, the exemplary transparent conductor sheet can be optimized around the transmissivity of the sheet and the direct current (DC) conductivity of the sheet. The transmissivity, T, of the film should be high so that light is easily passed through the film. The DC conductivity, σ_{DC}, of the film also needs to be high as well so that electrical current flows easily. The transmissivity is measured optically, typically at normal incidence, and either at a specified wavelength, often 550 nm, or over a range of wavelengths. Since the transparent conductor film is assumed to be thin, the current flowing in the film will be in the plane of the film. It is then convenient to report the sheet resistance, Rₛₕ, which should be a small since it is inversely proportional to the DC conductivity and the film thickness, t,

$${R}_{s h} = \frac{1}{{σ}_{D C} t}$$

A transparent conductor figure-of-merit can be defined to describe the design space for Rₛₕ and T. The transparent conductor figure-of-merit, ϕ, is the electrical to optical conductivity ratio (P. S. a. A. P. J. van de Groep, “Transparent conductiving silver nanowire networks,” Nano Letters, vol. 12, no. 6, pp. 3138-3144, 2012). which can be written in terms of the transmissivity, T, and the sheet resistance, Rₛₕ, as:

$$ϕ = \frac{{Z}_{0}}{2 {R}_{s h} ( {T}^{- 0.5} - 1 )}$$

where Z₀ is the impedance of free space (Z₀≈377Ω). Note that this transparent conductor figure-of-merit is dimensionless, and it increases with decreasing sheet resistance and increases with increasing transmissivity. Thus, larger values of the transparent conductor figure-of-merit indicate better transparent conductors. In some embodiments, the transparent conductor figure-of-merit is greater than 5000.

Various modifications, equivalent processes, as well as numerous structures to which the present invention may be applicable will be readily apparent to those of skill in the art to which the present invention is directed upon review of the present specification.

### EXAMPLES

### Test Methods

### Haze Measurements

A sample was placed BYK haze-gard i Transparency Transmission Haze Meter, available from BYK-Gardner (Columbia, Md.) and the transmission and haze of the sample were measured.

### Transmission Measurements

The transmission was measured with a LAMBDA 1050+ UV/Vis/NIR Spectrophotometer with a 150 mm integrating sphere accessory, from PerkinElmer (Waltham, Mass.). Samples were placed in the machine and measured transmission from 300 to 2500 in 5 nm increments. The solar direct transmission was calculated per ISO 9050—“Glass in Building—Determination of Light Transmittance, Solar Direct Transmittance, Total Solar Energy Transmittance, Ultraviolet Transmittance and Related Glazing Factors”.

### Sheet Resistance Measurements

The samples were cut to 50 mm×50 mm square and sheet resistance was measured on a Suragus EddyCus® TF Lab 4040a Non-Contact Electrical Anisotropy and Sheet Resistance Tester, available from Suragus GmbH (Dresden, Germany), that was calibrated to measure sheet resistances from 0.001Ω/□ to 200Ω/□. For samples where the sheet resistance was above 200Ω/□, a Delcom 707 Non-Contact Conductance Monitor from Delcom Instruments Inc. (Prescott, Wis.) was used to measure sheet resistance.

### 4-Point Resistance Measurement

A 4-point probe type resistance test was used to measure the resistance across the fold lines of samples subjected to the folding test by placing the probes on either side of the center that was creased. The 4 pt probe resistance tester was an Agilent 34401A Digital Multimeter, from Agilent Technologies, Santa Clara, Calif.

### Folding Test

In order to determine the bending tolerance of samples, a bending tester machine made to follow IEC 62715-6-1 “Flexible display devices—Part 6-1: Mechanical test methods—Deformation tests” was used to perform the bending cycles. A similar 2 axis clamshell bending machine can be found from Yuasa System Company (Okayama City, Japan).

A 50 mm×50 mm sample was adhered to the tester using Scotch® Double Sided Tape 665 available from 3M Company (St. Paul, Minn.). The adhesive was placed 2 mm from the edge such that the corresponding bending radius is approximately 3 mm when the film is folded. The film in all cases was placed such that the metal grid or ITO surface was the side folded together. The samples were then folded for the prescribed number of cycles and then a 4-point resistance probe, Agilent 34401A Digital Multimeter, from Agilent Technologies (Santa Clara, Calif.) was positioned over the fold such that 2 of the contact points were placed on each side of the fold. The testing was completed at room temperature.

### EXAMPLES

### Indium Tin Oxide (ITO) Coated Films

An ITO target comprising 90/10 wt. % mixture of In₂O₃ and SnO₂ from Umicore Electro-Optic Materials (Olen, Belgium) and indium were bonded to a ¼″ thick copper backing plate. The 5 in.×15 in. magnetron cathode was used to sputter the ITO are made by Sierra Applied Sciences, Inc. (Boulder, Colo.). The target and cathode assembly were mounted into a 14″ wide, roll-to-roll, sputtering system equipped with a 60° F. cooled coating drum from Mill Lane Engineering (Lowell, Mass.).

A roll of MELINX® ST504 Polyester film is a heat stabilized polyester film available from DuPont Teijin Films (Chester, Va.) was is loaded into the sputtering system. The chamber was closed the pressure inside of the system was reduced to less than 2.0×10⁻⁵ Torr.

ITO deposition was done in an argon atmosphere at a pressure of between 3 and 4 millitorr. Advanced Energy MDX DC power supplies were used to light the plasma and sputter the ITO. The film line speed was set to 2 fpm. The sputtered coated film passed through optical and conductivity monitors to establish a baseline transmission and conductivity and oxygen gas was then added in small steps to optimize the % T and the conductivity.

The line speed was adjusted to obtain different ITO coating thicknesses. After the desired length of material was run, the power supplies were shut off, the gas flow stopped, the pumps were isolated from the system and nitrogen gas was used to bring the pressure of the vacuum chamber back to atmospheric pressure. The chamber doors were opened and the coated roll/sample was removed. A summary of ITO coated PET films is provided in Table 1.

TABLE 1
Properties of ITO coated polyester films

| | ITO | Sheet | Solar Weighted | | |
|---|---|---|---|---|---|
| Comparative | Thickness | Resistance | Transmission (%) | | Haze |
| Example | (nm) | (Ω/ [symbol] ) | 300-2500 nm | 350-1500 nm | (%) |
| C1 | 0 | | 90.6 | 91.5 | 0.9 |
| C2 | 4 | 20000 | 87.6 | 88.3 | 0.9 |
| C3 | 8 | 1887 | 87.2 | 87.9 | 0.8 |
| C4 | 12 | 758 | 86.8 | 87.5 | 1.6 |
| C5 | 25 | 239 | 84.7 | 85.4 | 2.0 |
| C6 | 50 | 125 | 82.6 | 83.1 | 1.1 |
| C7 | 150 | 27 | 79.5 | 81.8 | 0.6 |

Polymer Films with Embedded Metal Grids

Exemplary transparent conductor sheets were prepared by the process outlined for articles 2-3 in PCT Publication No. WO2020/227280 and is incorporated herein by reference. In general, the process utilizes a microreplication tool consisting of features that are opposite of the features in the microstructured film. A conductive seed layer, (e.g. a silver ink), is applied to the highest features on the tool, i.e, interconnected ribs in which the embedded grid will be formed. The ink is dried and sintered. Next the tool, coated with conductive ink, is completely coated with a UV curable resin and covered with a film. The UV curable resin is cured and separated from the tool, which carries with the conductive ink seed layer in the bottom of the grooves formed in the polymeric substrate. This micro-structured polymeric substrate is then electroplated with copper which deposits on top of the silver ink seed layer. As the electroplating process continues the micro-structured channels confine the growth of the copper to within the confines of the grooves forming the embedded metal. A summary of exemplary transparent conductor sheets is provided in Table 2.

Some of the exemplary transparent conductor sheets were further coated with ITO on the exposed surface of the embedded coper grid and are provided in Table 2.

TABLE 2

| Properties of exemplary transparent conductor sheets | | | | | | | |
|---|---|---|---|---|---|---|---|
| | Groove | | ITO | Sheet | Solar Weighted | | |
| | Width | Pitch | Thickness | Resistance | Transmission (%) | | Haze |
| Example | (mm) | (mm) | (nm) | (W/□) | 300-2500 nm | 350-1500 nm | (%) |
| Ex. 1 | 10 | 300 | 0 | 0.03 | 82.7 | 82.1 | 4.8 |
| Ex. 2 | 10 | 300 | 4 | 0.03 | 79.5 | 78.8 | 5.3 |
| Ex. 3 | 10 | 300 | 8 | 0.03 | 79.5 | 78.9 | 6.5 |
| Ex. 4 | 10 | 300 | 12 | 0.03 | 79.3 | 78.7 | 5.7 |
| Ex. 5 | 10 | 300 | 25 | 0.04 | 76.9 | 76.3 | 4.9 |
| Ex. 6 | 3 | 150 | 0 | 0.12 | 84.6 | 83.9 | 9.3 |
| Ex. 7 | 4 | 300 | 0 | 0.11 | 83.9 | 83.5 | 7.8 |
| Ex. 8 | 25 | 1000 | 0 | 0.03 | 81.9 | 81.2 | 5.0 |
| Ex. 9 | 25 | 1000 | 0 | 0.45 | 85.9 | 85.5 | 3.6 |

TABLE 3
Resistance in Ohms for samples subiected to
a prescribed number of folding cycles

| | Number of Folding Cycles | | | |
|---|---|---|---|---|
| Sample | 0 | 10 | 100 | 500 |
| C2 | 73000 | 140000 | 220000 | 1500000 |
| C3 | 5600 | 6500 | 14100 | 28600 |
| C4 | 2060 | 2700 | 6000 | 11400 |
| C5 | 470 | 870 | 2400 | 6200 |
| C6 | 300 | 1400 | 5300 | 10200 |
| Ex. 1 | 0.08 | 0.10 | 0.10 | 0.10 |
| Ex. 2 | 0.10 | 0.11 | 0.10 | 0.17 |
| Ex. 3 | 0.11 | 0.12 | 0.11 | 0.10 |
| Ex. 4 | 0.11 | 0.09 | 0.12 | 0.10 |
| Ex. 5 | 0.11 | 0.1 | 0.09 | 0.10 |

### Modelling Sheet and Series Resistance of a Transparent Conductor Sheet

The sheet and series resistance of exemplary transparent conductor system with an embedded metal grid was modelled using a finite element method (Mathematica). An exemplary grid configuration was selected wherein the grid was a hexagonal copper grid having a 2 mm pitch and a conductive element width of 0.1 mm where the conductivity of copper was 4.54×10⁷ S/m. The overall size of the modelled grid was 10.4 mm×10 mm.

For the model, the photovoltaic cell was taken to be a stack of semiconductor materials with a top layer of transparent conducting oxides (TCO's), such as ITO, deposited on top of the semiconductor stack (see M. Zhang et al., “Electrode Design to Overcome Substrate Transparency Limitations for Highly Efficient 1 cm² Mesoscopic Perovskite Solar Cells,” Joule, Vol. 2, No. 12, pp. 2694-2705, December 2018). The transparent conducting oxide layer was modeled having a thickness of 100 nm and a sheet resistance is 44.5Ω/□ (M. Zhang, ibid.). Varying the thickness of the transparent conducting oxides layer varies the sheet resistance in an inverse relationship (“Sheet Resistance: A Guide to Theory”, Ossila Ltd., Sheffield, UK [online, https://www.ossila.com/pages/sheet-resistance-theory]).

For the sheet resistance, Dirichlet conditions are used at the minimum and maximum y-positions of the mesh to apply a potential difference, and the model is solved for the current distribution. To solve for the series resistance, a Dirichlet condition is used at the minimum y-position and a current source distribution is specified throughout the area, and the current distribution is solved for.

The sheet resistance for the metal mesh, 0.04Ω/□ is substantially lower than the sheet resistance for the transparent conducting oxide, 44.5Ω/□. The series resistance for the 100 nm thick transparent conducting oxide averages 18.6 Ohms-cm², whereas the transparent conductor with the embedded metal grid and 100 nm thick transparent conducting oxide has a series resistance that averages 5.83×10⁻² Ohms-cm². The same transparent conductor with the embedded metal grid with a 10 nm thick transparent conducting oxide has a series resistance that averages 4.78×10⁻¹ Ohms-cm², and transparent conductor with the embedded metal grid with a 1 nm thick transparent conducting oxide has a series resistance that averages 4.86 Ohms-cm². Thus, it is possible to achieve a lower series resistance with much thinner layer of the transparent conducting oxide and the exemplary transparent conductor with an embedded metal grid as described herein.

### Predicting Device Performance in a Photovoltaic Cell

To predict the device performance of a photovoltaic cell, a diode model is used (PVEducation see C. Honsberg and S. Bowden, “Double Diode Model”, PVCDROM, Solar Power Labs, ASU [online, https://www.pveducation.org/pvcdrom/characterisation/double-diode-model). The exact diode model is taken from the literature (see M. Zhang et al., “Electrode Design to Overcome Substrate Transparency Limitations for Highly Efficient 1 cm² Mesoscopic Perovskite Solar Cells,” Joule, Vol. 2, No. 12, pp. 2694-2705, December 2018) and (see M. Diethelm et al., “Finite element modeling for analysis of electroluminescence and infrared images of thin-film solar cells,” Solar Energy, Vol. 209, pp. 186-193, October).

The predicted device performance of photovoltaic cells comprising a transparent conductive sheet having an embedded metal grid and a thin ITO layer was determined based on fill-factor, short-circuit current, open circuit voltage Voc, and cell efficiency of the device. The calculations show that the exemplary materials with thin ITO layers are substantially better than a conventional photovoltaic cell design having only a 100 nm ITO layer and are summarized in Table 4.

TABLE 4
Device performance for a photovoltaic cell comprising a transparent conductor sheet
with an ITO layer compared to a conventional transparent conductor

| | Short-circuit | | | Series | Solar direct | | |
|---|---|---|---|---|---|---|---|
| ITO Thickness | Current | V_{oc} | Fill | Resistance | transmission | Cell | Open |
| (nm) | (mA/cm²) | [V] | Factor | (Ohm-cm²) | (350-1500 nm) | Efficiency | Fraction |
| 100 | 23.0 | 1.11 | 0.710 | 4.68E+00 | 80.5% | 0.193 | 0.9025 |
| 10 | 23.0 | 1.11 | 0.808 | 4.78E−01 | 91.8% | 0.220 | 0.9025 |
| 1 | 23.0 | 1.11 | 0.817 | 5.83E−02 | 92.8% | 0.222 | 0.9025 |
| Conventional | 21.7 | 1.12 | 0.500 | 1.86E−01 | | 0.122 | 1.000 |

### Optical Effects

The transmission spectra for ITO thicknesses on glass were calculated using the 4×4 matrix method using the Berreman algorithm to modeling the spectra of constructive and destructive interference generated from layer interfaces of materials having different refractive indices. The Berreman 4×4 matrix methodology was described in the Journal of the Optical Society of America (Volume 62, Number 4, April 1972) and the Journal of Applied Physics (Volume 85. Number 6, March 1999). Input parameters for this optical model were individual polymer refractive indices, polymer layer thicknesses, number of polymer layers, and reflection bandwidth including a left band edge and a right band edge. The Berreman methodology calculates the percent light reflected at each layer interface and the percent light transmitted at each layer interface and outputs a reflection spectra and transmission spectra.

The spectral refractive index sets for glass and ITO were obtained from PV Lighthouse Refractive Index Library (Refractive index library (pvlighthouse.com.au)).

The transmissivity of ITO depends on its thickness. Using the exemplary transparent conductor with the embedded metal grid and thinner ITO layers can boost the optical efficiency by approximately 3%. As a result, more light can be delivered to the solar cell. Increasing the light delivered to the solar cell by approximately % can results in a boost in the short-circuit current from 23.0 mA/cm² to 23.7 mA/cm², enhancing cell efficiency without compromising fill factor. Additionally, if the open fraction of the exemplary transparent conductor is increased to 0.95, the boost in the optical efficiency would be approximately 7%, resulting in a boost in the short-circuit current from 23.0 mA/cm² to 24.6 mA/cm².

### Effect of Broken Conductive Elements in the Embedded Metal Grid

The metal grid in the exemplary transparent conductors, described herein, can be modeled as a grid of resistors all connected to each other, and therefore the sheet resistance of such a mesh can be calculated by a graph theoretic approach (F. Dörfler, J. W. Simpson-Porco and F. Bullo, “Electrical Networks and Algebraic Graph Theory: Models, Properties, and Applications,” in Proceedings of the IEEE, vol. 106, no. 5, pp. 977-1005, May 2018, doi: 10.1109/JPROC.2018.2821924).

A 15×15 square grid of resistors was considered where a fraction of the connections were randomly chosen and disconnected. The sheet resistance of the resulting grid of resistors was then calculated. This was repeated many times, in this example 1000 times, and the results were ensemble averaged to calculate the average sheet resistance and to calculate the probability that the entire grid will disconnect, that is, that there will no longer be a path for current to flow from one edge to the opposite edge of the grid. This whole ensemble averaging procedure was then repeated at various values for the fraction of disconnected connections.

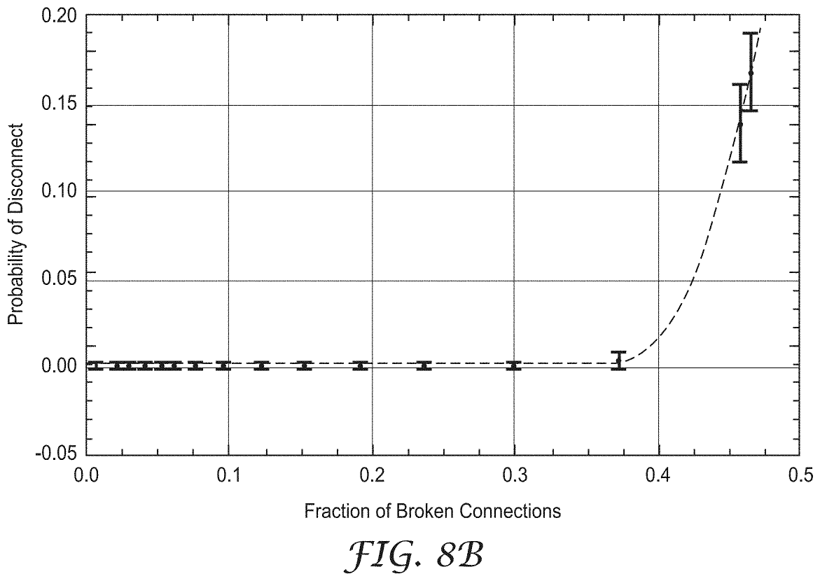

FIGS. 8A and 8B are graphs showing the probability of the embedded grid in the exemplary conductive sheet becoming completely disconnected as a function of the fraction of broken connections. The probability of the grid becoming completely disconnected does not occur until the fraction of the connections is greater than about 30%. FIG. 8A shows a linear plot of the probability of disconnection and FIG. 8B shows is a close up view of a portion of the graph shown in FIG. 8A. FIG. 8B shows that the onset of complete disconnection occurs for a fraction of broken connections in excess of 30%. The error bars show 95% confidence intervals.

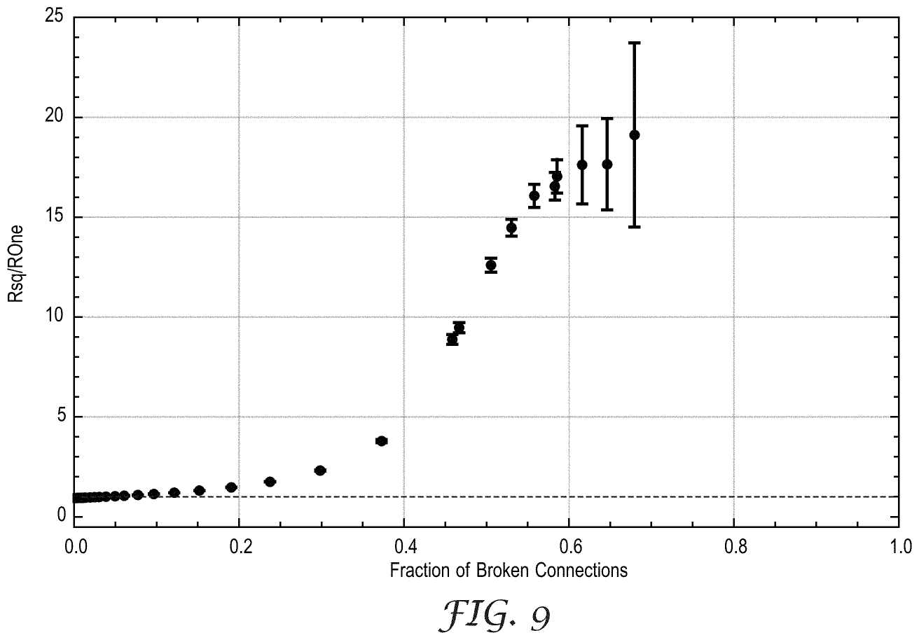

The steep rise in the sheet resistance of the resulting grid of resistors occurs when the fraction of broken connections is greater than about 30%, as shown in FIG. 9. The y-axis of this graph is labeled as R_{sq}/Rₒₙₑ where R_{sq} is the sheet resistance of the resulting grid and Rₒₙₑ is the resistance of one leg of the resistor network. Thus, the ratio of R_{sq}/Rₒₙₑ is a dimensionless way of reporting the sheet resistance of the resulting grid. The error bars show 95% confidence intervals.

### Comparison of Figures of Merit

The transmissivity of a transparent conductor depends on the conductor, the substrate, and other various layers that might comprise the film. In order to normalize this for conductive meshes, the substrate is assumed to be a plastic film with an index of refraction of 1.57 which is representative of plastics like PET.

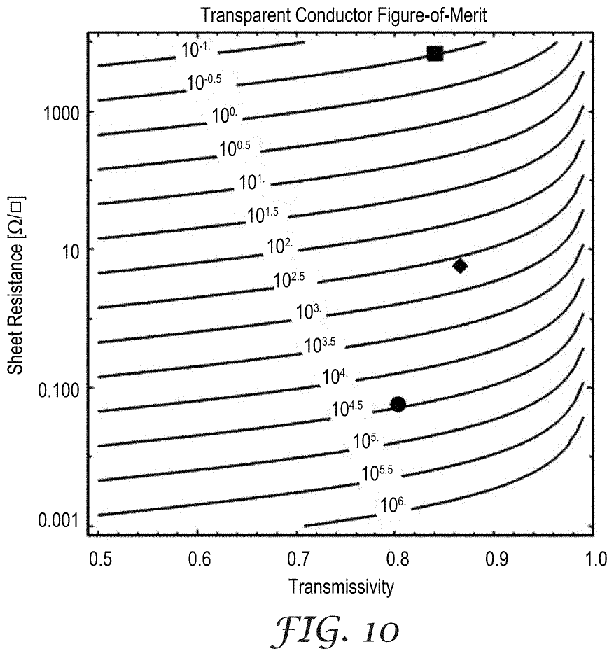

FIG. 10 is a graph showing the transparent conductor figure-of-merit, ϕ, as a function of the transmissivity. For the exemplary conductor sheets of examples Ex. 1-Ex. 9, the centroid of the figure-of-merit ϕ, based on the examples' transmissivity and sheet resistance is shown (●); the centroid of the figures-of-merit ϕ for the ITO conductor sheets of comparative examples C1-C7 is shown (▪); and the centroid of the figures-of-merit ϕ based on the transmissivity and sheet resistance of conductive sheets (Table 5) described in the literature (L1 and L2: section 6.2 of DOI: 10.5772/25901 https://www.intechopen.com/chapters/32590; L3: example 1 from JP2013102055; and L4: paragraph [0075] in EP3125306) is shown (♦). The transparent conductor figure-of-merit is approximately 30,000 for the exemplary conductor sheets described herein, while being approximately 0.3 for the ITO conductor sheets, and approximately 400 for the conductive sheets described in the literature.

TABLE 5
Values for transmissivity and sheet resistance used to calculate
transparent conductor figure-of-merit, ϕ for conductive sheets
from the literature

| | Sheet | Transmission |
|---|---|---|
| Literature | Resistance | at 550 nm |
| reference | (Ω/ [symbol] ) | (%) |
| L1 | 15.0 | 85.4 |
| L2 | 1.0 | 86.1 |
| L3 | 3.0 | 87.0 |
| L4 | 7.75 | 91.0 |

What is claimed is:

1. A solar cell comprising
a transparent conductor sheet comprising a polymeric substrate with an embedded metal grid, disposed within microchannels extending partially through a thickness of polymeric substrate from a first surface of the polymeric substrate; and
a photoactive layer disposed adjacent to the first surface of the polymeric substrate
wherein the transparent conductor sheet has a sheet resistance less than 1Ω/□ and an average solar direct transmittance over the visible and infrared portion of the spectrum of at least about 75%.

2. The solar cell of claim 1, further comprises one of an electron transport layer or a hole transport layer disposed between the transparent conductor sheet and the photoactive layer.

3. The solar cell of claim 2, wherein the electron transport layer or the hole transport layer comprises one of indium tin oxide (ITO) or poly(3,4-ethylenedioxythiophene) (PEDOT).

4. The solar cell of claim 2, wherein the electron transport layer or the hole transport layer is electrical contact with the embedded metal grid of the transparent conductor.

5. The solar cell of claim 4, wherein the embedded metal grid consists essentially of copper, nickel, or silver.

6. The solar cell of claim 1, wherein the embedded metal grid comprises a plurality of intersecting conductive elements having an aspect ratio greater than 0.5, wherein the aspect ratio is defined as element height divided by element width.

7. The solar cell of claim 6, wherein the conductive elements are disposed at a pitch between about 100 microns and about 5000 microns.

8. The solar cell of claim 6, wherein the transparent conductor sheet comprises open area between the plurality of intersecting conductive elements, wherein the open area is greater than about 80% of the first surface of the transparent conductor sheet.

9. The solar cell of claim 1, wherein the transparent conductor sheet further comprises a barrier assembly on a second surface of the polymeric substrate.

10. The solar cell of claim 9, further comprising a protective layer disposed on the barrier assembly.

11. The solar cell of claim 1, wherein the photoactive layer is a perovskite layer, a dye-sensitized assembly comprising a photoactive dye layer and an electrolyte layer, and an organic photovoltaic assembly comprising a buffer layer, an acceptor layer and a donor layer.

12. A transparent conductor sheet comprising
a polymeric substrate with an embedded metal grid, disposed within grooves formed in a first surface of the polymeric substrate; and
a barrier assembly disposed on a second surface of the polymeric substrate, wherein the barrier film consists of an inorganic oxide layer disposed between first and second polymer layers, wherein the first and second polymer layers each comprise a polymeric reaction product of at least one of acrylic or methacrylic monomers.

13. The transparent conductor sheet of claim 12, further comprising a protective layer bonded directly to exposed major surface of the barrier assembly, wherein the protective layer comprises one of a fluoropolymer or a polyurethane.

14. The transparent conductor sheet of claim 12, wherein the transparent conductor sheet has an average solar direct transmittance over the visible and infrared portion of the spectrum of at least about 80%.

15. The transparent conductor sheet of any of claim 12, wherein the embedded metal grid consists essentially of copper, nickel, or silver and comprises a plurality of intersecting conductive elements.

16. The transparent conductor sheet of claim 12, wherein the barrier assembly has a water vapor transmission rate (WVTR) that is less than about 0.01 g/m2/day at 38° C. and an oxygen transmission rate less than less than about 0.005 g/m2/day at 23°.

17. A method of making a flexible solar cell, comprising:
providing a transparent conductor sheet, wherein the transparent conductor sheet comprises a polymeric substrate with an embedded metal grid, disposed within grooves extending partially through a thickness of polymeric substrate from a first surface of the polymeric substrate;
optionally, applying an electron/hole transport layer on the first surface of the transparent conductor sheet; and
applying a photoactive layer on one of the first surface of the transparent conductor sheet and the electron/hole transport layer.

18. The method of claim 17, further comprising forming an electrode on the photoactive layer.

19. The method of claim 17, wherein the photoactive layer is a perovskite layer, a dye-sensitized assembly comprising a photoactive dye layer and an electrolyte layer, or an organic photovoltaic assembly comprising a buffer layer, an acceptor layer and a donor layer.

20. The method of claim 17, wherein the transparent conductor sheet further comprises a barrier assembly on a second surface of the polymeric substrate.
